(19) United States
(12) Patent Application Publication
(10) Pub. No.: US 2024/0025926 A1
(43) Pub. Date: Jan. 25, 2024

(54) POLYCYCLIC SILICON-GERMANIUM COMPOUNDS, PROCESSES FOR THEIR PREPARATION AND THEIR USE FOR PREPARING A SI- AND GE-CONTAINING SOLID

(71) Applicant: Johann Wolfgang Goethe-Universität, Frankfurt am Main (DE)

(72) Inventors: Matthias WAGNER, Maintal/Dörningheim (DE); Benedikt KÖSTLER, Kelkheim (DE); Hans-Wolfram LERNER, Oberursel (DE)

(73) Assignee: Johann Wolfgang Goethe-Universität, Frankfurt am Main (DE)

(21) Appl. No.: 18/254,389

(22) PCT Filed: Nov. 18, 2021
(86) PCT No.: PCT/DE2021/100913

§ 371 Date: May 25, 2023

(30) Foreign Application Priority Data
Nov. 27, 2020 (DE) 10 2020 131 425.6

(51) Int. Cl. C07F 7/30

(52) U.S. Cl. CPC C07F 7/30

(57) ABSTRACT

The present invention relates to a compound of formula (I)

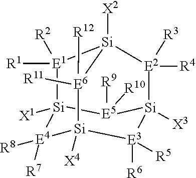

wherein E¹ to E⁶ are independently Si or Ge; X¹ to X⁴ are independently selected from the group consisting of H, SiH₃, halogen and Si(Y)₃; Y is independently selected from C₁ to C₂₀ alkyl and halogen; R¹ to R¹² are independently selected from the group consisting of C₁ to C₂₀ alkyl, C₂ to C₂₀ alkenyl, C₂ to C₂₀ alkynyl, C₃ to C₂₀ cycloalkyl, C₆ to C₂₀ aryl, C₇ to C₂₀ arylalkyl, C₇ to C₂₀ alkylaryl and Z; and Z is independently selected from the group consisting of H, halogen and C₁ to C₂₀ alkyl; a process for their preparation; and the use of the compound for preparing the Si- and Ge-containing solid.

### FIELD OF THE INVENTION

The present invention relates to polycyclic silicon-germanium compounds, a process for their preparation and their use for preparing a Si- and Ge-containing solid.

### BACKGROUND OF THE INVENTION

Halosilanes, polyhalosilanes, halogermanes, polyhalogermanes, silane, polysilanes, germane, polygermanes and corresponding mixed compounds have long been known, cf. in addition to the standard textbooks of inorganic chemistry also WO 2004/036631 A2 or C. J. Ritter et al., J. Am. Chem. Soc., 2005, 127, 9855-9864.

Triphenylgermylsilane and its preparation is described in EP 3 409 645 A1.

Chlorosilylarylgermanes and their preparation are disclosed in EP 3 410 466.

Ritter et al. J. Am. Chem. Soc. 2005, 127, 9855 describes the use of (H₃Ge)ₓSiH₄₋ₓ for producing semiconductor nanostructures on silicon.

Proceeding from the prior art, it is desirable to prepare improved silicon-germanium compounds, in particular storable silicon-germanium compounds, and to provide a flexible process for the simple preparation of a multiplicity of such compounds. It is likewise desirable to provide compounds which can be used to produce Si/Ge solid bodies.

The object of the present invention is to overcome disadvantages of the prior art, in particular to prepare storable, tailored silicon-germanium compounds which are suitable for the preparation of Si/Ge solid bodies.

### Overview of the Invention

This object is achieved by a compound of formula (I)

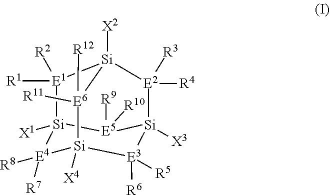

wherein E¹ to E⁶ are independently Si or Ge; X¹ to X⁴ are independently selected from the group consisting of H, SiH₃, halogen and Si(Y)₃; Y is independently selected from C₁ to C₂₀ alkyl and halogen; R¹ to R¹² are independently selected from the group consisting of C₁ to C₂₀ alkyl, C₂ to C₂₀ alkenyl, C₂ to C₂₀ alkynyl, C₃ to C₂₀ cycloalkyl, C₆ to C₂₀ aryl, C₇ to C₂₀ arylalkyl, C₇ to C₂₀ alkylaryl and Z; and Z is independently selected from the group consisting of H, halogen and C₁ to C₂₀ alkyl.

It may be provided that at least three of E¹ to E⁶ are Ge and the remaining of E¹ to E⁶ are Si. It may be provided that four, five or six of E¹ to E⁶ are Ge and the remaining of E¹ to E⁶ are Si. It may be provided that four or five of E¹ to E⁶ are Ge and the remaining of E¹ to E⁶ are Si.

It may be provided that R¹ to R¹² are independently selected from the group consisting of C₁ to C₁₂ alkyl, C₂ to C₁₂ alkenyl, C₂ to C₁₂ alkynyl, C₃ to C₁₂ cycloalkyl, C₆ to C₁₂ aryl, C₇ to C₁₃ arylalkyl, C₇ to C₁₃ alkylaryl, and halogen.

It may be provided that R¹ to R¹² are independently selected from the group consisting of C₁ to C₁₂ alkyl, C₆ to C₁₂ aryl, C₇ to C₁₃ arylalkyl, C₇ to C₁₃ alkylaryl, and halogen.

It may be provided that R¹ to R¹² are independently selected from the group consisting of C₁ to C₂₀ alkyl, C₆ to C₂₀ aryl and halogen.

It may be provided that R¹ to R¹² are independently selected from the group consisting of C₁ to C₁₂ alkyl and halogen.

It may be provided that R¹ to R¹² are independently C₁ or methyl.

It may be provided that two Rⁿ directly connected to the same E^{m} (that is, the two R in the pairs R¹ and R², R³ and R⁴, R⁵ and R⁶, R⁷ and R⁸, R⁹ and R¹⁰, and R¹¹ and R¹²) are the same.

It may be provided that in the case that the E^{m} (that is, one of E¹ to E⁶) is Ge, the two Rⁿ directly connected to the E^{m} are C₁ to C₂₀ alkyl. It may be provided that in the case that the E^{m} (that is, one of E¹ to E⁶) is Ge, the two Rⁿ directly connected to the E^{m} are C₁ to C₁₂ alkyl. It may be provided that in the case that the E^{m} (that is, one of E₁ to E₆) is Ge, the two Rⁿ directly connected to the E^{m} are C₁ to C₈ alkyl. It may be provided that in the case that the E^{m} (that is, one of E¹ to E⁶) is Ge, the two Rⁿ directly connected to the E^{m} are C₁ to C₄ alkyl. It may be provided that in the case that the E^{m} (that is, one of E¹ to E⁶) is Ge, the two Rⁿ directly connected to the E^{m} are methyl.

It may be provided that in the case that the E^{m} (that is, one of E¹ to E⁶) is Si, the two Rⁿ directly connected to the E^{m} are halogen. It may be provided that in the case that the E^{m} (that is, one of E¹ to E⁶) is Si, the two Rⁿ directly connected to the E^{m} are C₁.

It may be provided that X¹ to X⁴ are independently selected from the group consisting of H, SiH₃, Si(C₁ to C₂₀ alkyl)₃, Cl and SiCl₃. It may be provided that X¹ to X⁴ are independently selected from the group consisting of H, SiH₃, Si(C₁ to C₁₂ alkyl)₃, C₁ and SiCl₃. It may be provided that X¹ to X⁴ are independently selected from the group consisting of H, SiH₃, Si(C₁ to C₈ alkyl)₃, C₁ and SiCl₃. It may be provided that X¹ to X⁴ are independently selected from the group consisting of H, SiH₃, Si(C₁ to C₄ alkyl)₃, Cl and SiCl₃. It may be provided that X¹ to X⁴ are independently selected from the group consisting of Si(C₁ to C₄ alkyl)₃ and SiCl₃.

It may be provided that the compound of formula (I) is selected from one of the following compounds C₁ to C₄.

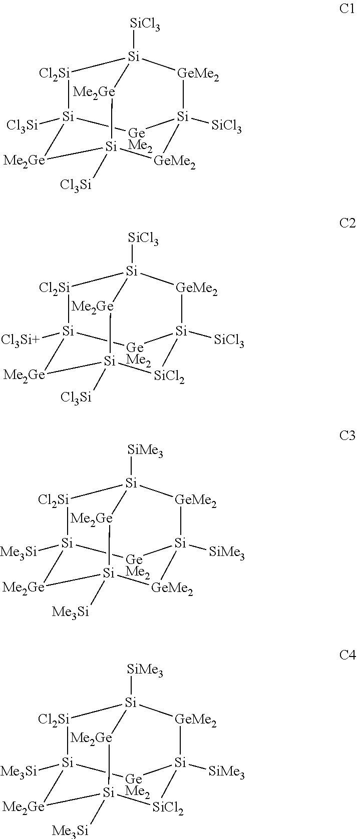

The object is further achieved by a process for preparing a compound of formula (I) according to any one of the preceding claims comprising reacting a compound of formula (II)

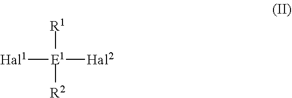

with a compound of formula (III)

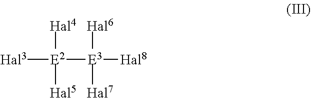

wherein Hal¹ to Hal⁸ are independently halogen; and R¹ and R² are as defined above; and
crystallizing the product of the reaction of compounds (II) and (III).

It may be provided that in the process E¹=Ge and E² and E³ are each Si.

The molar ratio of compound (II) to compound (III) may be from 10:1 to 1:40; 5:1 to 1:2; 2:1 to 1:20; 1.5:1 to 1:10; 1.2:1 to 1:8; 1:3 to 1:5, approximately 1:4.

It may be provided that the reaction of the compound of formula (II) with the compound of formula (III) is carried out in the presence of a catalyst. It may be provided that the catalyst is used in amounts of from 0.001 to 1 eq., preferably from 0.01 to 0.1 eq. It may be provided that the catalyst is a base. It may be provided that the catalyst is a phosphorus- or nitrogen-containing base. It may be provided that the catalyst is a nitrogen-containing base. It may be provided that the catalyst is a phosphonium or ammonium salt. It may be provided that the catalyst is selected from [(R³)₄P]Cl or [(R³)₄N]Cl, wherein the radicals R³ are independently selected from C₁ to C₁₂ alkyl, C₆ to C₁₂ aryl, C₇ to C₁₃ arylalkyl and C₇ to C₁₃ alkylaryl. It may be provided that the catalyst is [(R³)₄N]Cl, wherein R³ is selected from methyl, ethyl, isopropyl, n-butyl and phenyl. It may be provided that the catalyst is [(R³)₄N]Cl, wherein R³ is selected from n-butyl.

It may be provided that the reaction of the compound of formula (II) with the compound of formula (III) is carried out in a solvent. In the process, at least 5 mol of solvent per mol of compound (III), alternatively from 10 mol to 100 mol of solvent per mol of compound (III) may be used. It may be provided that the solvent is an organic solvent. It may be provided that the solvent (both in the reaction step and in the hydrogenation step) is a non-polar organic solvent. It may be provided that the solvent is selected from n-pentane, n-hexane, n-heptane, cyclohexane, toluene, diethyl ether, dichloromethane, chloroform, tert-butyl methyl ether, acetone and tetrahydrofuran. It may be provided that the solvent is dichloromethane.

It may be provided that the reaction of the compound of formula (II) with the compound of formula (III) is carried out at a temperature in a range from 0° C. to 50° C., 10° C. to 40° C., 15° C. to 30° C., 20° C. to 25° C., or 22° C. (=room temperature).

It may be provided that the reaction of the compound of formula (II) with the compound of formula (III) is carried out for 5 min to 24 h, 30 min to 12 h, or 1 h to 4 h.

It may be provided that the process further comprises reacting the product obtained after crystallization with a Grignard reagent. A Grignard reagent is a compound of general formula R—Mg-Hal with R=acyl (such as aryl or alkyl) and Hal=halogen (such as Cl or Br). Such a compound can be prepared by reacting acyl halide with magnesium in a suitable organic solvent. Suitable organic solvents are those which can form a coordinate bond to the Mg in the R—Mg-Hal through a free electron pair. An ether (preferably a dialkyl ether such as diethyl ether or a cyclic ether such as tetrahydrofuran (THF)) is preferably used as organic solvent. Grignard reagents and their preparation and use are well known from the state of the art, in particular from relevant textbooks of organic chemistry.

It may be provided that a compound of formula (I) with X¹ to X⁴=SiAcyl₃ is obtained by reacting a compound of formula (I) with X¹ to X⁴=SiHal₃ with a Grignard reagent of formula R—Mg-Hal with R=Acyl in THF or diethyl ether. It may be provided that a compound of formula (I) with X¹ to X⁴=SiAlkyl₃ is obtained by reacting a compound of formula (I) with X¹ to X⁴=SiHal₃ with a Grignard reagent of formula R—Mg-Hal with R=Alkyl in THF or diethyl ether. It may be provided that a compound of formula (I) with X¹ to X⁴═Si(C₁ to C₄ alkyl)₃ is obtained by reacting a compound of formula (I) with X¹ to X⁴═SiCl₃ with a Grignard reagent of formula R—Mg-Hal with R═C₁ to C₄ alkyl in diethyl ether. It may be provided that a compound of formula (I) with X¹ to X⁴═SiMe₃ is obtained by reacting a compound of formula (I) with X¹ to X⁴═SiCl₃ with a Grignard reagent of formula R—Mg-Hal with R=methyl in diethyl ether.

The object is likewise achieved by the use of a compound described above for preparing an Si- and Ge-containing solid.

It may be provided that the Si- and Ge-containing solid is an intermetallic phase, wherein the two semimetals Si and Ge are to be regarded as metals in this context. An intermetallic phase (also intermetallic compound) is a chemical compound of two or more metals. In contrast to alloys, the intermetallic phase shows lattice structures which differ from those of the constituent metals. The lattice bond of the different types of atoms is a mixed form of a predominantly metallic bond and smaller proportions of other types of bond (covalent bond, ionic bond), whereby these phases have particular physical and mechanical properties.

It may be provided that the preparation of the Si- and Ge-containing solid comprises heating the compound to a temperature of 300° C. or more. It may be provided that the preparation of the Si- and Ge-containing solid comprises heating the compound to a temperature of 400° C. or more. It may be provided that the preparation of the Si- and Ge-containing solid comprises heating the compound to a temperature of 450° C. or more. It may be provided that the preparation of the Si- and Ge-containing solid comprises heating the compound to a temperature of 500° C. or more. It may be provided that the preparation of the Si- and Ge-containing solid comprises heating the compound to a temperature of 550° C. or more. It may be provided that the preparation of the Si- and Ge-containing solid comprises heating the compound to a temperature of 600° C. or more. It may be provided that the preparation of the Si- and Ge-containing solid comprises heating the compound to a temperature of 400° C. to 1000° C.. It may be provided that the preparation of the Si- and Ge-containing solid comprises heating the compound to a temperature of 400° C. to 800° C. It may be provided that the preparation of the Si- and Ge-containing solid comprises heating the compound to a temperature of 450° C. to 750° C. It may be provided that the preparation of the Si- and Ge-containing solid comprises heating the compound to a temperature of 500° C. to 700° C. It may be provided that the preparation of the Si- and Ge-containing solid comprises heating the compound to a temperature of 550° C. to 650° C. It may be provided that the preparation of the Si- and Ge-containing solid comprises heating the compound to a temperature of about 600° C.

It may be provided that the preparation of the Si- and Ge-containing solid comprises depositing SiGe. It may be provided that the preparation of the Si- and Ge-containing solid comprises simultaneously depositing Si and Ge. It may be provided that the stoichiometric ratio of Si to Ge in the Si- and Ge-containing solid corresponds to the stoichiometric ratio of Si to Ge in the compound of formula (I). It may be provided that the stoichiometric ratio of Si to Ge in the Si- and Ge-containing solid corresponds to the stoichiometric ratio of Si to Ge in the compound of formula (I) with a deviation of ±10%.

It may be provided that the Si- and Ge-containing solid contains further elements in an amount of 10% by weight or less, based on the total weight of the Si- and Ge-containing solid. It may be provided that the Si- and Ge-containing solid contains further elements in an amount of 5% by weight or less, based on the total weight of the Si- and Ge-containing solid. It may be provided that the Si- and Ge-containing solid contains further elements in an amount of 3% by weight or less, based on the total weight of the Si- and Ge-containing solid. It may be provided that the Si- and Ge-containing solid contains further elements in an amount of 2% by weight or less, based on the total weight of the Si- and Ge-containing solid. It may be provided that the Si- and Ge-containing solid contains further elements in an amount of 1% by weight or less, based on the total weight of the Si- and Ge-containing solid. It may be provided that the Si- and Ge-containing solid contains further elements in an amount of 0.5% by weight or less, based on the total weight of the Si- and Ge-containing solid. It may be provided that the Si- and Ge-containing solid contains further elements in an amount of 0.1% by weight or less, based on the total weight of the Si- and Ge-containing solid. It may be provided that the Si- and Ge-containing solid contains further elements in an amount of 0.01% by weight or less, based on the total weight of the Si- and Ge-containing solid. It may be provided that the Si- and Ge-containing solid contains further elements in an amount of 0.001% by weight or less, based on the total weight of the Si- and Ge-containing solid.

It may be provided that further elements contained in the Si- and Ge-containing solid are selected from the group consisting of carbon, oxygen, aluminum and mixtures thereof.

It may be provided that the heating of the compound of formula (I)

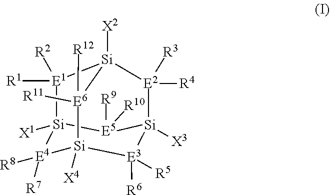

during the preparation of the Si- and Ge-containing solid is accompanied by the formation of R¹—H and R²—H.

The term “alkyl” as used herein refers to mono-radical of a saturated chain-shaped or branched hydrocarbon. Preferably, the alkyl group comprises 1 to 12 (about 1 to 10) carbon atoms, i.e. 1, 2, 3, 4, 5, 6, 7, 8, 9, 10, 11 or 12 carbon atoms, preferably 1 to 8 carbon atoms, alternatively 1 to 6 or 1 to 4 carbon atoms. Exemplary alkyl groups are methyl, ethyl, propyl, isopropyl, butyl, isobutyl, tert-butyl, n-pentyl, isopentyl, sec-pentyl, neopentyl, 1,2-dimethylpropyl, isoamyl, n-hexyl, isohexyl, sec-hexyl, n-heptyl, isoheptyl, n-octyl, 2-ethylhexyl, n-nonyl, n-decyl, n-undecyl or n-dodecyl.

The term “alkenyl” as used herein refers to the mono-radical of a saturated chain-shaped or branched hydrocarbon having at least one double bond.

The term “alkynyl” as used herein refers to the mono-radical of a saturated chain-shaped or branched hydrocarbon having at least one triple bond.

The term “aryl” as used herein refers to the mono-radical of an aromatic cyclic hydrocarbon. Preferably, the aryl group contains 5 to 14 (for example 5, 6, 7, 8, 9, 10) carbon atoms, which may be arranged in one ring (for example “phenyl”=“Ph”) or in two or more condensed rings (for example “naphthyl”). Exemplary aryl groups are, for example, cyclopentadienyl, phenyl, indenyl, naphthyl, azulenyl, fluorenyl, anthryl, and phenanthryl.

The term “cycloalkyl” as used herein refers to the cyclic, non-aromatic form of an alkyl.

The term “arylalkyl” as used herein refers to an aryl group which is substituted with at least one alkyl, for example tolueneyl.

The term “alkylaryl” as used herein refers to an alkyl group which is substituted with at least one aryl, for example 2-phenylethyl.

The term “halogen” as used herein refers to fluorine, chlorine, bromine or iodine.

### DETAILED DESCRIPTION OF THE INVENTION

The invention will be described in detail below with reference to particularly preferred embodiments and exemplary embodiments. However, the invention is not limited to these particularly preferred embodiments and exemplary embodiments, wherein individual features of the particularly preferred embodiments and exemplary embodiments together with other features or features of the preceding general disclosure of the invention can serve to implement the invention.

The present invention relates to the novel polycyclic silicon-germanium compounds of formula (I)

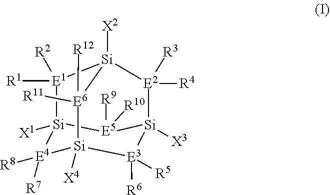

Corresponding compounds are obtainable via a novel synthesis, for example proceeding from diorganyldichlorogermane and hexachlorodisilane. For example, the target compounds (I) can be prepared by addition of tetrabutylammonium chloride and optional subsequent reaction with a Grignard reagent. These polycyclic silicon-germanium compounds are distinguished by their thermolysis behavior, for example in the deposition of pure Si and Ge, wherein the residue obtained here consists of pure Si and Ge in the stoichiometric ratio.

### Synthesis Examples

### Synthesis of C₁₀H₃₀Cl₁₄Ge₅Si₉ (C1)

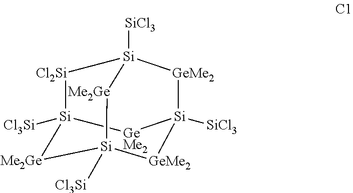

[nBu₄N]Cl (161 mg, 0.58 mmol, 0.2 eq.), Me₂GeCl₂ (500 mg, 2.88 mmol, 1 eq.), 10 ml CH₂Cl₂ and Si₂Cl₆ (3092 mg, 11.5 mmol, 4 eq.) were stirred at room temperature for 3 hours and then all volatile constituents were removed under reduced pressure. The crude product was washed twice with 5 ml n-hexane each time and the residue was dissolved in CH₂Cl₂. Over time, a colorless solid crystallized out. Washing with CH₂Cl₂ yielded C1 (4%, 32 mg, 0.025 mmol) as a colorless crystalline solid. The product was characterized by X-ray diffractometry (orthorhombic, Cmc21) and NMR spectroscopy.

¹H NMR (500.2 MHz, CD₂Cl₂, 298 K): δ=1.00, 0.94, 0.93 ppm.

¹³C{¹H} NMR (125.8 MHz, CD₂Cl₂, 298 K): δ=2.57, 2.23, 1.97 ppm.

²⁹Si NMR (99.4 MHz, CD₂Cl₂, 298 K): δ=16.2, 12.1, −80.7, −83.3 ppm.

### Synthesis of C₈H₂₄Cl₁₆Ge₄Si₁₀ (C2)

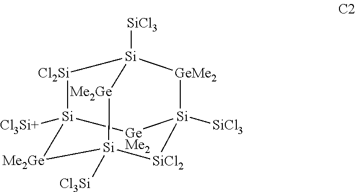

[nBu₄N]Cl (161 mg, 0.58 mmol, 0.2 eq.), Me₂GeCl₂ (500 mg, 2.88 mmol, 1 eq.), 10 ml CH₂Cl₂ and Si₂Cl₆ (3092 mg, 11.5 mmol, 4 eq.) were filled into a sealed bottle. After a few days, colorless crystals had formed, which could be isolated by filtration. Washing with CH₂Cl₂ yielded C2 (18%, 163 mg, 0.13 mmol) as a colorless crystalline solid. The product was characterized by X-ray diffractometry (trigonal, R−3) and NMR spectroscopy.

¹H NMR (500.2 MHz, CD₂Cl₂, 298 K): δ=1.03 ppm.
¹³C{¹H} NMR (125.8 MHz, CD₂Cl₂, 298 K): δ=1.59 ppm.
²⁹Si NMR (99.4 MHz, CD₂Cl₂, 298 K): δ=11.9, −80.8 ppm.

### Synthesis of C₂₂H₆₆Cl₂Ge₅Si₉ (C3)

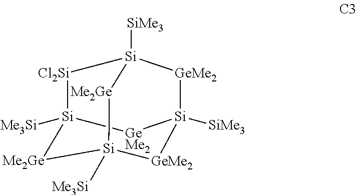

C1 (12 mg, 0.009 mmol, 1 eq.) and 0.5 ml Et₂O were filled into an NMR tube and an Et₂O solution of MeMgBr (3 M, 0.1 ml, 0.30 mmol, 30 eq.) was added while cooling with ice. The NMR tube was melted in under vacuum. After about two weeks at room temperature, complete conversion could be observed by NMR spectroscopy. The NMR tube was then opened, the contents were transferred together with 3 ml Et₂O into a Schlenk flask and then 0.05 ml MeOH was added while cooling with ice. After stirring for 10 minutes, all volatile constituents were removed and the residue was extracted with a total of 7 ml n-hexane. All volatile constituents were again removed from the extract, whereupon C₃ (82%, 8 mg, 0.008 mmol) was obtained as a colorless crystalline solid. The product was characterized by X-ray diffractometry (orthorhombic, Cmcm) and NMR spectroscopy.

¹H NMR (500.2 MHz, CD₂Cl₂, 298 K): δ=0.66, 0.61, 0.59, 0.35, 0.27 ppm.
¹³C{¹H} NMR (125.8 MHz, CD₂Cl₂, 298 K): δ=4.06, 3.81, 3.60, 3.27, 2.92 ppm.
²⁹Si NMR (99.4 MHz, CD₂Cl₂, 298 K): δ=−2.6, −3.5, −91.5, −97.2 ppm.

### Synthesis of C₂₀H₆₀Cl₄Ge₄Si₁₀ (C4)

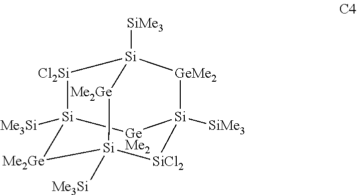

C2 (20 mg, 0.015 mmol, 1 eq.) and 0.5 ml Et₂O were filled into an NMR tube and an Et₂O solution of MeMgBr (3 M, 0.2 ml, 0.60 mmol, 40 eq.) was added while cooling with ice. The NMR tube was melted in under vacuum. After heating for 14 h at 60° C., complete conversion could be observed by NMR spectroscopy. Further purification was then carried out analogously to C3.

Finally, C4 (89%, 16 mg, 0.016 mmol) was obtained as a colorless crystalline solid. The product was characterized by X-ray diffractometry (orthorhombic, Pbca) and NMR spectroscopy.

¹H NMR (500.2 MHz, CD₂Cl₂, 298 K): δ=0.70, 0.37 ppm.
¹³C{¹H} NMR (125.8 MHz, CD₂Cl₂, 298 K): δ=3.7, 2.5 ppm.
²⁹Si NMR (99.4 MHz, CD₂Cl₂, 298 K): δ=−1.8, −91.6 ppm.

The features of the invention disclosed in the above description and in the claims can be essential both individually and in any combination for the realization of the invention in its various embodiments.

1. A compound of formula (I) 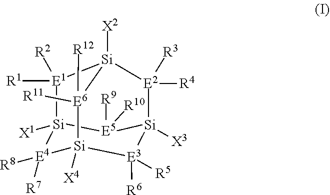
wherein
E¹ to E⁶ are independently Si or Ge;
X¹ to X⁴ are independently selected from the group consisting of H, SiH₃, halogen and Si(Y)₃;
Y is independently selected from C₁ to C₂₀ alkyl and halogen;
R¹ to R¹² are independently selected from the group consisting of C₁ to C₂₀ alkyl, C₂ to C₂₀ alkenyl, C₂ to C₂₀ alkynyl, C₃ to C₂₀ cycloalkyl, C₆ to C₂₀ aryl, C₇ to C₂₀ arylalkyl, C₇ to C₂₀ alkylaryl and Z; and
Z is independently selected from the group consisting of H, halogen and C₁ to C₂₀ alkyl.

2. A compound according to claim 1, wherein at least three of E¹ to E⁶ are Ge and the remaining of E₁ to E⁶ are Si.

3. A compound according to claim 1, wherein R¹ to R¹² are independently selected from the group consisting of C₁ to C₂₀ alkyl and halogen.

4. A compound according to claim 1, wherein R¹ to R¹² are independently selected from the group consisting of methyl and Cl.

5. A compound according to claim 1, wherein X¹ to X⁴ are independently selected from the group consisting of H, SiH₃, Si(C₁ to C₄ alkyl)₃, Cl and SiCl₃.

6. A compound according to claim 1, wherein X¹ to X⁴ are independently selected from the group consisting of SiCl₃ and Si(CH₃)₃.

7. A process for preparing a compound of formula (I) according to claim 1 comprising
reacting a compound of formula (II) 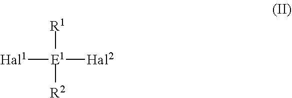
with a compound of formula (III) 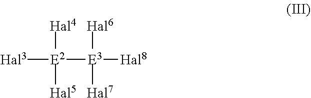
wherein
Hal¹ to Hal⁸ are independently halogen; and
R¹ and R² are as defined in any one of the preceding claims; and
crystallizing the product of the reaction of compounds (II) and (III).

8. The process according to claim 7, wherein the reaction of the compound of formula (II) with the compound of formula (III) is carried out in the presence of a catalyst.

9. The process according to claim 7, further comprising reacting the product obtained after crystallization with a Grignard reagent.

10. (canceled)
